(19) United States
(12) Patent Application Publication
(10) Pub. No.: US 2024/0071939 A1
(43) Pub. Date: Feb. 29, 2024

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Jung-Wei Cheng, Hsinchu City (TW); Tsung-Ding Wang, Tainan (TW); Yu-Min Liang, Taoyuan City (TW); Hao-Cheng Hou, Hsinchu City (TW)

(73) Assignee: Taiwan Semiconductor Manufacturing Company, Ltd., Hsinchu (TW)

(21) Appl. No.: 17/897,196

(22) Filed: Aug. 28, 2022

(51) Int. Cl. H01L 23/538; H01L 21/48; H01L 21/56; H01L 21/683; H01L 23/31

(52) U.S. Cl. CPC H01L 23/5383; H01L 21/4853; H01L 21/4857; H01L 21/565; H01L 21/6835; H01L 23/3121; H01L 23/5386; H01L 23/5389; H01L 2221/68359

(57) ABSTRACT

A semiconductor structure includes a composite redistribution structure, a first interconnect device and an integrated circuit (IC) package component. The composite redistribution structure includes a first redistribution structure, a second redistribution structure and a third redistribution structure. The second redistribution structure is located between the first redistribution structure and the third redistribution structure. The first interconnect device is embedded in the second redistribution structure. The first interconnect device includes a plurality of metal connectors leveled with a surface of the second redistribution structure and electrically connected to the third redistribution structure. The IC package component is disposed over the third redistribution structure and electrically connected to the first interconnect device via the third redistribution structure.

### BACKGROUND

Contemporary high performance computing systems consisting of one or more electronic devices have become widely used in a variety of advanced electronic applications. When integrated circuit components or semiconductor chips are packaged for these applications, one or more chip packages are generally bonded to a circuit carrier (e.g., a system board, a printed circuit board, or the like) for electrical connections to other external devices or electronic components. To respond to the increasing demand for miniaturization, higher speed and better electrical performance (e.g., lower transmission loss and insertion loss), more creative packaging and assembling techniques are actively researched.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1M are schematic cross-sectional views of a manufacturing method of a semiconductor structure according to an embodiment of the disclosure.

FIGS. 2A-2E are schematic cross-sectional views of partial steps of a manufacturing method of a semiconductor structure according to another embodiment of the disclosure.

FIG. 3 is a schematic cross-sectional view of a third redistribution structure according to some embodiments.

FIGS. 4A-4F are schematic cross-sectional views of partial steps of a manufacturing method of a semiconductor structure according to another embodiment of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

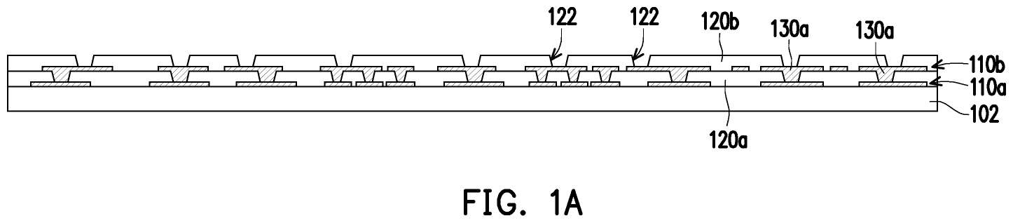

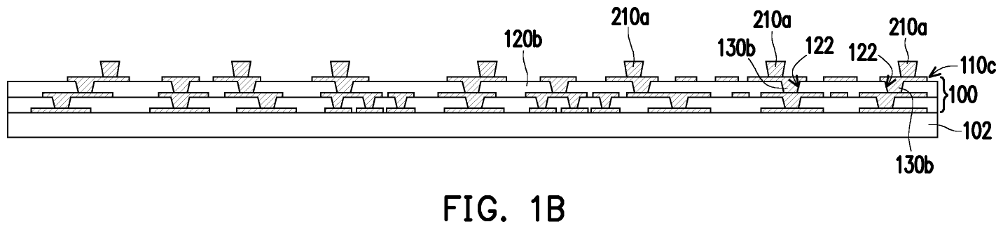

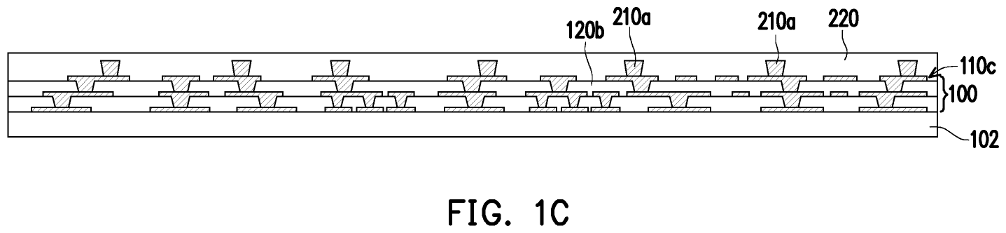

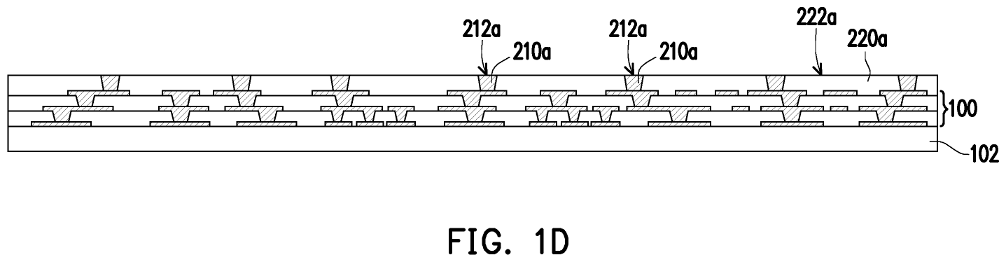

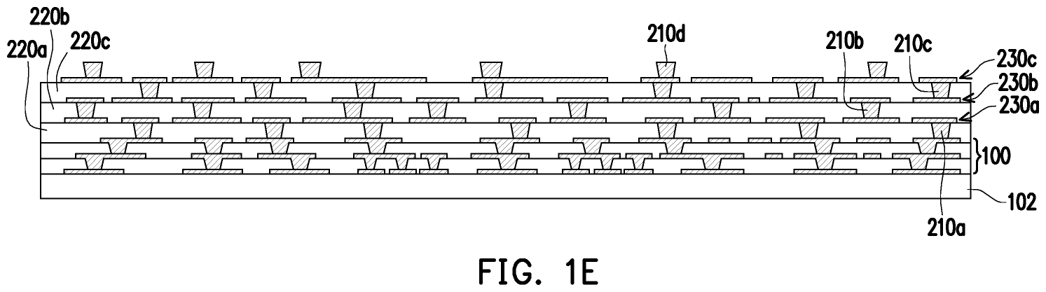

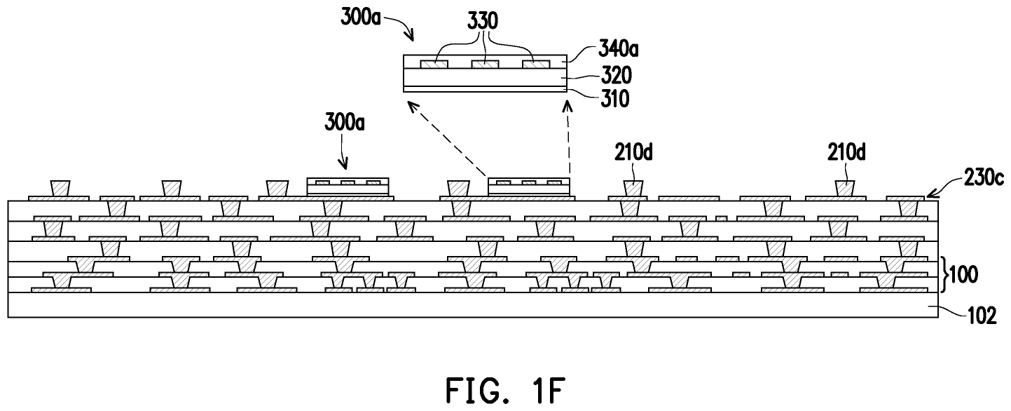

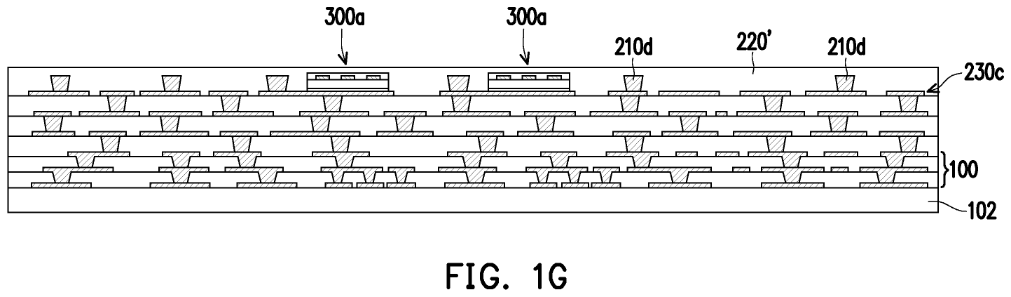

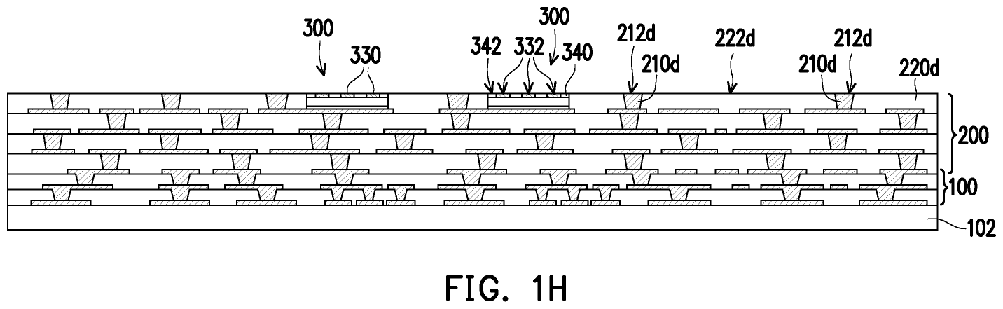

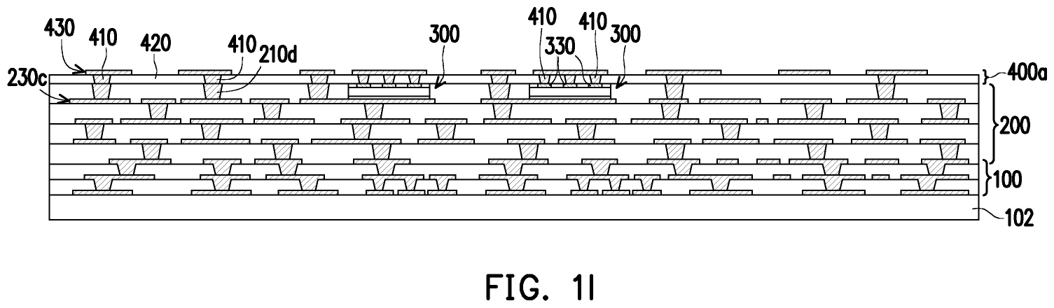

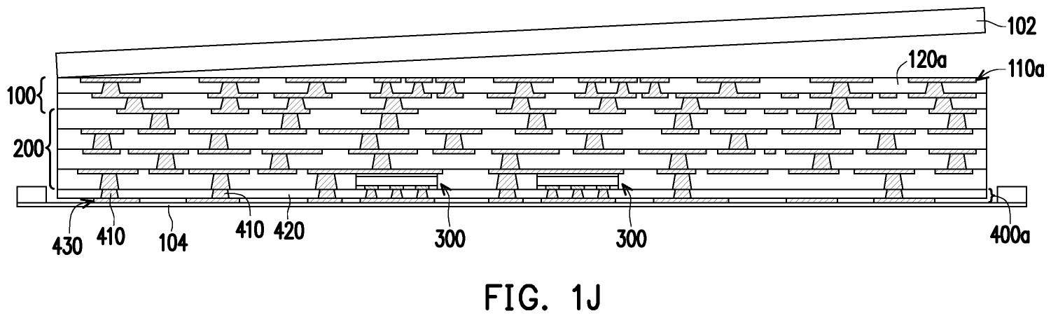

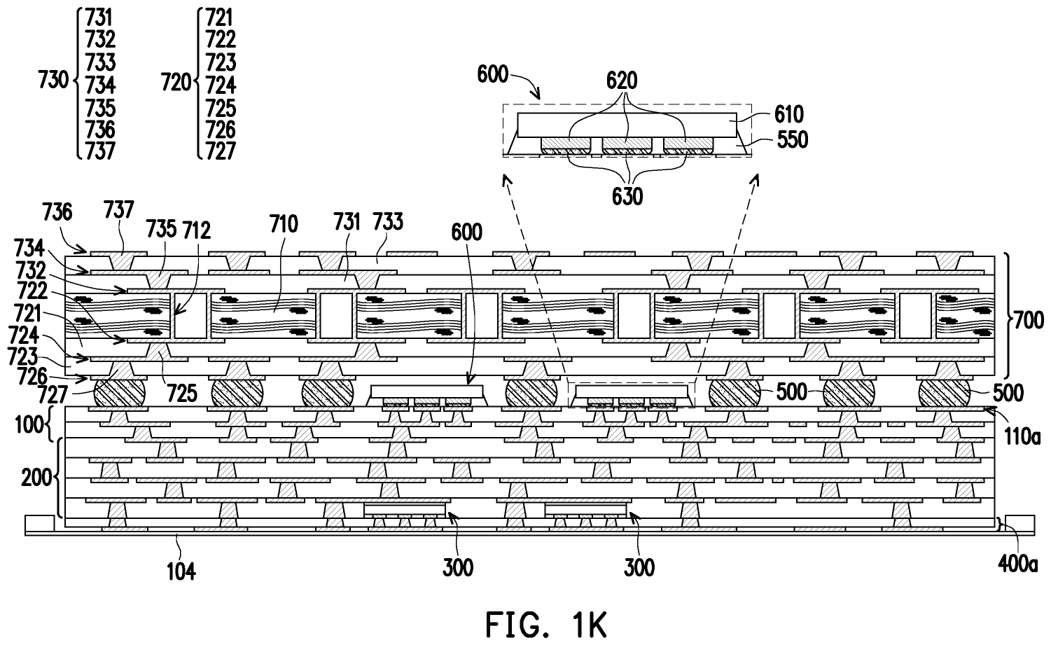

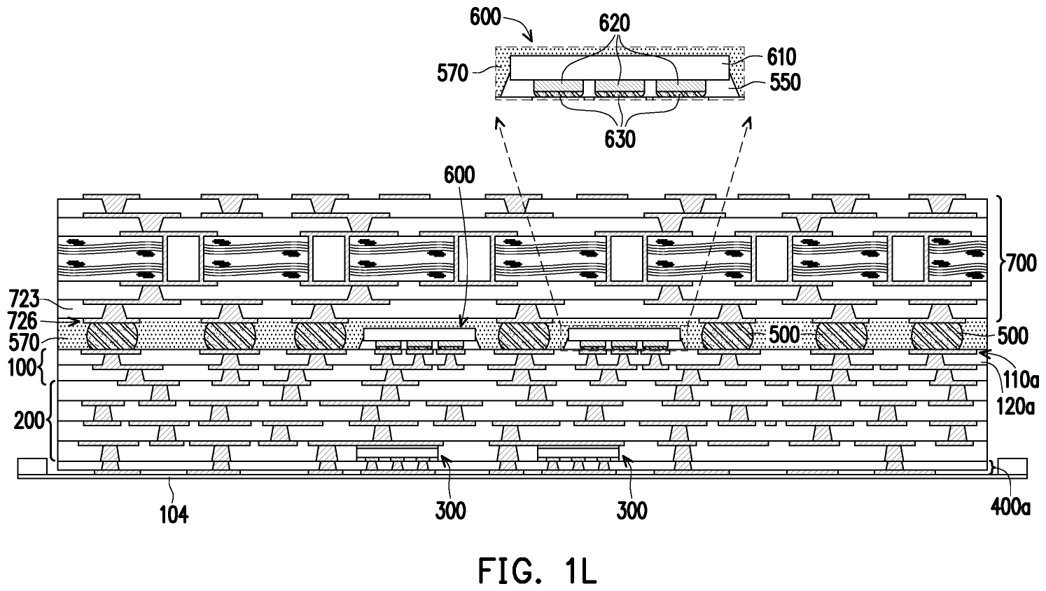

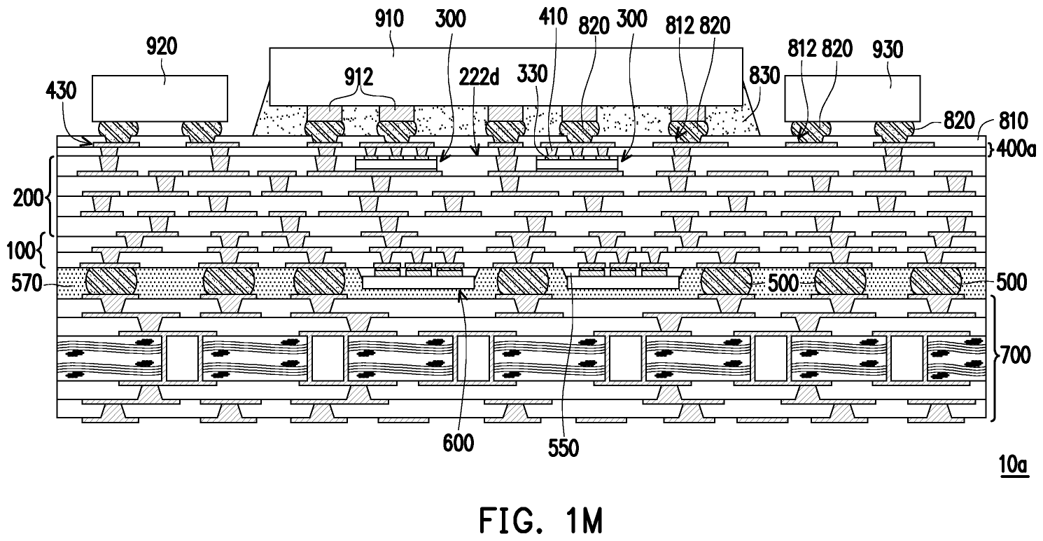

FIGS. 1A-1M are schematic cross-sectional views of a manufacturing method of a semiconductor structure according to an embodiment of the disclosure. Referring to FIG. 1A, two layers of conductive patterns 110a, 110b (e.g., conductive pads and conductive lines), two layers of dielectric layers 120a, 120b and a plurality of conductive vias 130a may be formed over a first temporary carrier 102. In some embodiments, the first temporary carrier 102 may include, for example, silicon-based materials, such as a silicon substrate (e.g., a silicon wafer), a glass material, a ceramic material, silicon oxide, or other materials, such as aluminum oxide, the like, or a combination, that can support the structure formed thereon during processing. In some embodiments, a release layer (not shown) may be formed on the top surface of the first temporary carrier 102 to facilitate subsequent debonding of first temporary carrier 102. In some embodiments, the release layer may be formed of a polymer-based material, which may be removed along with the first temporary carrier 102 from the overlying structures that will be formed in subsequent steps. In some embodiments, the release layer is an epoxy-based thermal-release material, which loses its adhesive property when heated, such as a Light-to-Heat-Conversion (LTHC) release coating. In other embodiments, the release layer may be an ultra-violet (UV) glue, which loses its adhesive property when exposed to UV light. The release layer may be dispensed as a liquid and cured, may be a laminate film laminated onto the first temporary carrier 102, or the like. The top surface of the release layer may be leveled and may have a high degree of co-planarity.

The conductive patterns 110a may be formed on the first temporary carrier 102 and expose a portion of the first temporary carrier 102. The dielectric layer 120a may be formed on the conductive patterns 110a and the first temporary carrier 102 to cover the conductive patterns 110a and the first temporary carrier 102 exposed by the conductive patterns 110a. The conductive patterns 110b may be formed on the dielectric layer 120a and expose a portion of the dielectric layer 120a. The conductive vias 130a extend through the dielectric layer 120a to physically and electrically couple the conductive patterns 110b and the conductive patterns 110a. The dielectric layer 120b having a plurality of opening 122 may be formed on the conductive patterns 110b and the dielectric layer 120a to cover the conductive patterns 110b and the dielectric layer 120a exposed by the conductive patterns 110b.

Referring to FIG. 1B and with reference to FIG. 1A, conductive vias 130b may be formed in the opening 122 of the dielectric layer 120b, and the conductive patterns 110c may be formed on the dielectric layer 120b and expose a portion of the dielectric layer 120b. In an embodiment, the conductive patterns 110c (or 110b, or 110a) and the conductive vias 130b (or 130a) may be formed by initially forming a seed layer (not shown). In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using a suitable formation process such as PVD, CVD, sputtering, or the like. The seed layer is formed over the dielectric layer 120b (or 120a) and sidewalls of the openings 122. A photoresist (also not shown) may then be formed to cover the seed layer and then be patterned to expose those portions of the seed layer that are located where the conductive patterns 110c (or 110b, or 110a) and the conductive vias 130b (or 130a) will subsequently be formed. Once the photoresist has been formed and patterned, a conductive material may be formed on the seed layer. The conductive material may be a material such as copper, titanium, tungsten, aluminum, another metal, the like, or a combination thereof. The conductive material may be formed through a deposition process such as electroplating, electroless plating, or the like. However, while the material and methods discussed are suitable to form the conductive material, these are merely examples. Any other suitable materials or any other suitable processes of formation, such as CVD or PVD, may alternatively be used to form the conductive patterns 110c (or 110b, or 110a) and the conductive vias 130b (or 130a). Once the conductive material has been formed, the photoresist may be removed through a suitable removal process such as an ashing process or a chemical stripping process, such as using oxygen plasma or the like. Additionally, after the removal of the photoresist, those portions of the seed layer that were covered by the photoresist may be removed through, for example, a suitable wet etch process or dry etch process, which may use the conductive material as an etch mask. The remaining portions of the seed layer and conductive material form the conductive patterns 110c (or 110b, or 110a) on the dielectric layer 120b (or 120a) and the conductive vias 130b (or 130a) in the opening 122. An insulating layer may be formed then openings 122 made through the insulating layer to form the dielectric layer 120b (or 120a) and expose portions of the underlying conductive patterns 110b (or 110a) using a suitable photolithographic mask and etching process. A seed layer may be formed over the dielectric layer 120b (or 120a) and the opening 122, and conductive material formed on portions of the seed layer, forming the conductive patterns 110c (or 110b, or 110a) and the conductive vias 130b (or 130a). These steps may be repeated to form a first redistribution structure 100 having a suitable number and configuration of the conductive patterns (i.e., 110a, 110b, 110c), the dielectric layers (i.e., 120a, 120b), and the conductive vias (i.e., 130a,130b).

Referring to FIG. 1C and with reference to FIG. 1B, a plurality of vias 210a may be formed on the conductive patterns 110c of the first redistribution structure 100, and then a dielectric film 220 may be formed on the first redistribution structure 100 to cover the vias 210a, the conductive patterns 110c and the dielectric layer 120b exposed by the conductive patterns 110c. The dielectric film 220 may fill gaps between the vias 210a and the conductive patterns 110c, and the dielectric film 220 may further bury the vias 210a and the conductive patterns 110c. In some embodiments, the dielectric film 220 is formed of a polymer, such as polybenzoxazole (PBO), polyimide, benzocyclobutene (BCB), or the like. In other embodiments, the dielectric film 220 is an underfill, which may or may not comprise a filler material (e.g., silicon oxide). In still other embodiments, the dielectric film 220 is formed of a nitride such as silicon nitride; an oxide such as silicon oxide, phosphosilicate glass (PSG), borosilicate glass (BSG), boron-doped phosphosilicate glass (BPSG), or the like; or the like. The dielectric film 220 may be formed by any acceptable deposition process, such as lamination, spin coating, CVD, the like, or a combination thereof. Optionally, the dielectric film 220 may be cured after deposition. In other embodiments, the dielectric film 220 may be replaced with a molding compound, epoxy, or the like, which may be applied by compression molding, transfer molding, lamination, or the like.

Referring to FIG. 1D and with reference to FIG. 1C, a planarization process may be performed on the dielectric film 220 to form a dielectric layer 220a which exposes a top surface 212a of the via 210a. In some embodiments, the planarization process may also remove material of the vias 210a. The top surfaces 212a of the vias 210a and a surface 222a of the dielectric layer 220a may be coplanar after the planarization process. The planarization process may be, for example, a grinding process, a chemical-mechanical polish (CMP), or the like.

Referring to FIG. 1E, a redistribution layer 230a may then be formed on the dielectric layer 220a. In an embodiment, the redistribution layer 230a may be formed using materials and processes similar to the conductive patterns 110a, 110b, 110c. For example, a seed layer may be formed, a photoresist placed and patterned on top of the seed layer in a desired pattern for the redistribution layer 230a. Conductive material (e.g., copper, titanium, or the like) may then be formed in the patterned openings of the photoresist using e.g., a plating process. The photoresist may then be removed and the seed layer etched, forming the redistribution layer 230a. In this manner, the redistribution layer 230a may form electrical connections to the vias 210a. Next, a plurality of vias 210b, a dielectric layer 220b, a redistribution layer 230b, a plurality of vias 210c, a dielectric layer 220c, a redistribution layer 230c and a plurality of vias 210d are sequentially formed on the redistribution layer 230a. The vias 210b, 210c, and 210d may be formed using similar materials and similar processes as the vias 210a and further description of the vias 210b, 210c, and 210d is omitted for brevity. The dielectric layers 220b and 220c may be formed using similar materials and similar processes as the dielectric layer 220a and further description of the dielectric layers 220b and 220c is omitted for brevity. The redistribution layers 230b and 230c may be formed using similar materials and similar processes as the redistribution layer 230a and further description of the redistribution layers 230b and 230c is omitted for brevity.

Referring to FIG. 1F and with reference to FIG. 1E, first interconnect devices 300a may be attached to the redistribution layer 230c. FIG. 1F also shows a magnified view of an example first interconnect device 300a. In some embodiments, the first interconnect devices 300a may be attached to any one of the redistribution layers 230a, 230b or 230c. In some embodiments, the first interconnect device 300a may be included a die attach film 310, a main body 320, a plurality of metal connectors 330 and a protective layer 340a. The main body 320 may be disposed on the die attach film 310, and the first interconnect device 300a can be positioned on the redistribution layer 230c through the die attach film 310. The metal connectors 330 may be formed on a single side of the main body 320, and may be used to make electrical connections to the main body 320. In some embodiments, the metal connectors 330 comprises metal pillars (such as copper pillars). The metal connectors 330 may include a conductive material such as copper, aluminum, gold, nickel, silver, palladium, tin, the like, or a combination thereof. In some embodiments, the metal pillars may be solder-free and/or have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. The protective layer 340a may be formed on the main body 320 and may fill gaps between the metal connectors 330, and the protective layer 340a may further bury the metal connectors 330. The protective layer 340a may be formed from one or more suitable dielectric materials such as a polymer material, a polyimide material, a polyimide derivative, an oxide, a nitride, a molding compound, the like, or a combination thereof. In some embodiments, the first interconnect devices 300a comprises passive devices, for example, capacitors, resistors, inductors, or the like. FIG. 1F shows two first interconnect devices 300a attached to the redistribution layer 230c, but in other embodiments, only one or more than two first interconnect devices 300a may be attached.

Referring to FIG. 1G, a dielectric film 220′ may be formed on the redistribution layer 230c to cover the redistribution layer 230c, the vias 210d and the first interconnect devices 300a. The dielectric film 220′ may fill gaps between the vias 210d, the redistribution layer 230c and the first interconnect devices 300a, and the dielectric film 220′ may further bury the redistribution layer 230c, the vias 210d and the first interconnect devices 300a. In some embodiments, the dielectric film 220′ is formed of a polymer, such as polybenzoxazole (PBO), polyimide, benzocyclobutene (BCB), or the like. In other embodiments, the dielectric film 220′ is an underfill, which may or may not comprise a filler material (e.g., silicon oxide). In still other embodiments, the dielectric film 220′ is formed of a nitride such as silicon nitride; an oxide such as silicon oxide, phosphosilicate glass (PSG), borosilicate glass (BSG), boron-doped phosphosilicate glass (BPSG), or the like; or the like. The dielectric film 220′ may be formed by any acceptable deposition process, such as lamination, spin coating, CVD, the like, or a combination thereof. Optionally, the dielectric film 220′ may be cured after deposition. In other embodiments, the dielectric film 220′ may be replaced with a molding compound, epoxy, or the like, which may be applied by compression molding, transfer molding, lamination, or the like.

Referring to FIG. 1H and with reference to FIG. 1G, a planarization process may be performed on the dielectric film 220′ to form a dielectric layer 220d, a protective layer 340 and first interconnect devices 300, and to expose a top surface 212d of the via 210d and a top surface 332 of the metal connectors 330. The planarization process may also remove material of the vias 210d and the metal connectors 330. The top surfaces 212d of the vias 210d, a surface 222d of the dielectric layer 220d, the top surface 332 of the metal connectors 330 and a surface 342 of the protective layer 340 may be coplanar after the planarization process. The planarization process may be, for example, a chemical-mechanical polish (CMP), a grinding process, or the like. So far, a second redistribution structure 200 having a suitable number and configuration of the vias (i.e., 210a, 210b, 210c, 210d), the dielectric layers (i.e., 220a, 220b, 220c, 220d) and the redistribution layers (i.e., 230a, 230b, 230c) is formed, and the first interconnect devices 300 are embedded in the second redistribution structure 200. In some embodiments, the second redistribution structure 200 is a fan-out structure.

Referring to FIG. 1I, a third redistribution structure 400a may be directly formed on the second redistribution structure 200. The third redistribution structure 400a includes a plurality of vias 410, a dielectric layer 420 and a redistribution layer 430. The vias 410 may be directly formed on the second redistribution structure 200 to physically and electrically couple the redistribution layer 430 and the redistribution layer 230c. The dielectric layer 420 may be laminated on the second redistribution structure 200 to expose the vias 410, and the redistribution layer 430 may be formed on the dielectric layer 420. In some embodiments, the vias 410, the dielectric layer 420 and the redistribution layer 430 may be formed using similar materials and similar processes as the vias 210d (or 210c, 210b, 210a), the dielectric layer 220c (or 220b or 220a) and the redistribution layer 230c (or 230b or 230a) and further description of the vias 410, the dielectric layer 420 and the redistribution layer 430 is omitted for brevity. Here, the first interconnect devices 300 are physically and electrically connected to the third redistribution structure 400a without using solder connections. The metal connectors 330 of the first interconnect devices is directly connected to the vias 410 of the third redistribution structure 400a. The first redistribution structure 100, the second redistribution structure 200 and the third redistribution structure 400a define a composite redistribution structure, which is an integrated fan-out structure (InFO).

Referring to FIG. 1J and with reference to FIG. 1I, the structure shown in FIG. 1I may be transferred to be placed on a tape frame 104, and the first temporary carrier 102 may be released through a de-bonding process. In some embodiments, the de-bonding includes projecting a light such as a laser light or an UV light on a release layer on the first temporary carrier 102 so that the release layer decomposes under the heat of the light and the first temporary carrier 102 can be removed. In some embodiments, the structure is flipped over and placed on the tape frame 104, where the redistribution layer 430 may face downward and may be disposed on the tape frame 104. After the de-bonding process of the first temporary carrier 102, the conductive patterns 110a and the dielectric layers 120a of the first redistribution structure 100 may be accessibly revealed.

Referring to FIG. 1K, second interconnect devices 600 are attached to a surface of the first redistribution structure 100 relatively far away from the second redistribution structure 200. FIG. 1K also shows a magnified view of an example second interconnect device 600. In some embodiments, the second interconnect device 600 includes a main body 610, a plurality of conductive connectors 620 and solder material 630. The conductive connectors 620 may be used to make electrical connections to the main body 610. The second interconnect device 600 shown in FIG. 1K have conductive connectors 620 formed on a single side of each main body 610, but in some embodiments, a second interconnect device 600 may have conductive connectors 620 formed on both sides of each main body 610. In some embodiments, the conductive connectors 620 comprise metal pads or metal pillars (such as copper pillars). The conductive connectors 620 may include a conductive material such as solder, copper, aluminum, gold, nickel, silver, palladium, tin, the like, or a combination thereof. In some embodiments, the metal pillars may be solder-free and/or have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In some embodiments, the solder material 630 is formed on each conductive connector 620 prior to attachment. In some embodiments, the solder material 630 formed on the conductive connectors 620 may be ball grid array (BGA) connectors, solder balls, controlled collapse chip connection (C4) bumps, micro bumps (e.g., μpbumps), electroless nickel-electroless palladium-immersion gold technique (ENEPIG) formed bumps, or the like. In some embodiments, the solder material 630 is formed by initially forming a layer of solder through evaporation, electroplating, printing, solder transfer, ball placement, or the like. Once a layer of solder has been formed on the conductive connectors 620, a reflow may be performed in order to shape the material into the desired shapes. The second interconnect devices 600 may be placed on the first redistribution structure 100, for example, using e.g., a pick-and-place process. In some embodiments, once the solder material 630 of the second interconnect devices 600 is in physical contact with the first redistribution structure 100, a reflow process may be performed to bond the solder material 630 to the first redistribution structure 100 and thus attach the second interconnect devices 600 to the first redistribution structure 100. That is, the second interconnect devices 600 are coupled to the first redistribution structure 100 using solder connection. In some embodiments, the second interconnect devices 600 comprises passive devices, for example, capacitors, resistors, inductors, or the like. FIG. 1K shows two second interconnect devices 600 attached to the first redistribution structure 100, but in other embodiments, only one or more than two second interconnect devices 600 may be attached.

In some embodiments, an underfill 550 may be deposited in the gap between each main body 610 of the second interconnect devices 600 and the first redistribution structure 100. The underfill 550 may be a material such as a molding compound, an epoxy, an underfill, a molding underfill (MUF), a resin, or the like. The underfill 550 can protect the conductive connectors 620 and provide structural support for the main body 610 of the second interconnect devices 600. In some embodiments, the underfill 550 may be cured after deposition.

With continued reference to FIG. 1K, a substrate component 700 is provided and may be bonded the first redistribution structure 100. The substrate component 700 may be or may include an organic substrate, a ceramic substrate, a silicon substrate, or the like. The substrate component 700 may include active and passive devices (not shown), or may be free from either active devices, passive devices, or both. Utilizing the substrate component 700 has the advantage of having the substrate component 700 being manufactured in a separate process. In some embodiments, because the substrate component 700 is formed in a separate process, the substrate component 700 may be individually or batch tested, validated, and/or verified prior to bonding the substrate component 700 to the first redistribution structure 100.

Before being coupled to the first redistribution structure 100, the substrate component 700 may be processed according to applicable manufacturing processes to form redistribution structures in the substrate component 700. In some embodiments, the substrate component 700 is a core substrate which includes a core layer 710. The core layer 710 may be formed of organic and/or inorganic materials. For example, the core layer 710 may include one or more layers of glass fiber, resin, filler, pre-preg, epoxy, silica filler, ABF, polyimide, molding compound, other materials, and/or combinations thereof. In some embodiments, the core layer 710 includes one or more passive components (not shown) embedded inside. The core layer 710 may include other materials or components. Alternatively, the substrate component 700 is a coreless substrate. The substrate component 700 may include through core vias 712 extending through the core layer 710 for providing vertical electrical connections between two opposing sides of the core layer 710. In some embodiments, the through core vias 712 are hollow through vias having centers that are filled with an insulating material. In some embodiments, the through core vias 712 are solid conductive pillars.

In some embodiments, the substrate component 700 includes a fourth redistribution structure 720 and a fifth redistribution structure 730 electrically coupled by the through core vias 712, and fan-in/fan-out electrical signals. For example, some of the through core vias 712 are coupled between conductive features of the fourth redistribution structure 720 at one side of the core layer 710 and conductive features of the fifth redistribution structure 730 at an opposite side of the core layer 710. The fourth redistribution structure 720 and the fifth redistribution structure 730 each include dielectric layers 721,723, 731, 733, formed of ABF, pre-preg, or the like, and metallization patterns. Each respective metallization pattern has line portions 722, 724, 726, 732, 734, 736 on and extending along a major surface of a respective dielectric layer 721, 723, 731, 733, and has via portions 725, 727, 735, 737 extending through the respective dielectric layer 721, 723, 731, 733. More or fewer dielectric layers and metallization patterns may be formed in the fourth redistribution structure 720 and the fifth redistribution structure 730 than shown in FIG. 1K.

With continued reference to FIG. 1K, the fourth redistribution structure 720 may be attached to the conductive patterns 110a of the first redistribution structure 100 through conductive joints 500. For example, attaching the substrate component 700 includes placing conductive bumps of the substrate component 700 on the conductive patterns 110a of the first redistribution structure 100 and reflowing the conductive bumps to form the conductive joints (or solder connections) 500 that are physically and electrically coupled the substrate component 700 and the conductive patterns 110a of the first redistribution structure 100. The conductive bumps may be ball grid array (BGA) connectors or the like. The conductive bumps may include a conductive material such as solder, copper, aluminum, gold, nickel, silver, palladium, tin, the like, or a combination thereof. In some embodiments, the conductive bumps are formed by initially forming a layer of solder through evaporation, electroplating, printing, solder transfer, ball placement, or the like. Once a layer of solder has been formed on the structure, a reflow may be performed in order to shape the material into the desired bump shapes. In some embodiments, the conductive bumps are first formed on either the substrate component 700 or the conductive patterns 110a of the first redistribution structure 100, and then reflowed to complete the bond. That is, the first redistribution structure 100 is coupled to the substrate component 700 using solder connection.

In some embodiments, a singulation process is performed to form a coterminous sidewall, where the sidewall may include outer sidewalls of the third redistribution structure 400a, the second redistribution structure 200, the first redistribution structure 100, the protective layer 570 and substrate component 700.

Referring to FIG. 1L, a protective layer 570 may be formed in a gap between the first redistribution structure 100 and the substrate component 700 to securely bond the associated elements and provide structural support and environmental protection. FIG. 1L also shows a magnified view of an example second interconnect device 600. For example, the protective layer 570 surrounds the conductive joints 500, the underfill 550 and the second interconnect devices 600, and covers the conductive patterns 110a and the exposed surfaces of dielectric layer 120a of the first redistribution structure 100, and the line portions 726 and the exposed surfaces of the dielectric layer 723 of the fourth redistribution structure 720. In some embodiments, the protective layer 570 is formed of molding compound such as a resin, polyimide, PPS, PEEK, PES, epoxy molding compound (EMC), another material, the like, or a combination thereof. In some embodiments, the protective layer 570 is formed of an underfill material, and may be dispensed by a capillary flow process or the like. The protective layer 570 may be applied in liquid or semi-liquid form and then subsequently cured.

Referring to FIG. 1M and with reference to FIG. 1L, the structure is removed from the tape frame 104 through a de-taping process in order to accessibly expose the redistribution layer 430 for further processing. In some embodiments, after the de-taping process, the structure is flipped over and placed on another tape frame (not shown) for the subsequent mounting process, where the substrate component 700 may be attached to the tape frame. In some embodiments, a dielectric layer 810 may be formed for protecting the features of the third redistribution structures 400a. In some embodiments, an integrated circuit (IC) package component 910 and electronic devices 920, 930 are mounted on the third redistribution structure 400a through a plurality of external connectors 820 after bonding the substrate component 700. In some embodiments, the external connectors 820 are first formed on either the composite redistribution structure or the IC package component 910 and the electronic devices 920, 930, and then reflowed to complete the bond.

The IC package component 910 may include IC dies such as one or more logic dies (e.g., central processing unit (CPU), graphics processing unit (GPU), system-on-a-chip (SoC), application processor (AP), microcontroller, etc.), one or more memory dies (e.g., dynamic random access memory (DRAM) die, static random access memory (SRAM) die, etc.), one or more power management dies (e.g., power management integrated circuit (PMIC) die), one or more radio frequency (RF) dies, one or more sensor dies, one or more micro-electro-mechanical-system (MEMS) dies, one or more signal processing dies (e.g., digital signal processing (DSP) die), one or more front-end dies (e.g., analog front-end (AFE) dies), one or more input/output (I/O) dies, the like, or combinations thereof. The electronic devices 920, 930 may be, for example, a die (e.g., an integrated circuit die, power integrated circuit die, logic die, or the like), a chip, a semiconductor device, a memory device (e.g., SRAM or the like), a passive device (e.g., an integrated passive device (IPD), a multi-layer ceramic capacitor (MLCC), an integrated voltage regulator (IVR), or the like), the like, or a combination thereof. The electronic devices 920, 930 may comprise one or more active devices such as transistors, diodes, or the like and/or one or more passive devices such as capacitors, resistors, inductors, or the like. The embodiment illustrated in FIG. 1M includes a system-on-a-chip (i.e., 910) and two multi-layer ceramic capacitors (i.e., 920, 930).

With continued reference to FIG. 1M, the IC package component 910 and the electronic devices 920, 930 are physically and electrically connected to the external connectors 820 to make electrical connection between the IC package component 910 and the third redistribution structure 400a and between the electronic devices 920, 930 and the third redistribution structure 400a. The IC package component 910 may have bond pads 912 that are bonded to the external connectors 820. In some embodiments, IC package component 910 may be picked and placed over the third redistribution structure 400a and bonded to the external connectors 820 by flip-chip bonding process or other suitable bonding process. The external connectors 820 flow into the opening 812 of the dielectric layer 810 after reflow and electrically connect the bond pads 912 of the IC package component 910 and the redistribution layer 430. The electronic devices 920, 930 may be located in regions between adjacent the IC package component 910, and the electronic devices 920,930 may be electrically connected to the third redistribution structure 400a by the external connectors 820. The electronic devices 920, 930 may be electrically connected to the IC package component 910 by the external connectors 820 and the redistribution layer 430 of the third redistribution structure 400a.

In some embodiments, the external connectors 820 may be controlled collapse chip connection (C4) bumps, solder balls, micro bumps (e.g., μpbumps), electroless nickel-electroless palladium-immersion gold technique (ENEPIG) formed bumps, or the like. The external connectors 820 may include a conductive material such as solder, copper, aluminum, gold, nickel, silver, palladium, tin, the like, or a combination thereof. In some embodiments, the external connectors 820 is formed by initially forming a layer of solder through evaporation, electroplating, printing, solder transfer, ball placement, or the like. Once a layer of solder has been formed on the external connectors 820, a reflow may be performed in order to shape the material into the desired shapes.

Still referring to FIG. 1M, an underfill layer 830 may be formed in a gap between the IC package component 910 and the dielectric layer 810 to securely bond the IC package component 910 to the third redistribution structure 400a and to provide structural support and environmental protection. The underfill layer 830 may be formed by a capillary flow process after the IC package component 910 are attached, or may be formed by a suitable deposition method. The underfill layer 830 may surround the bond pads 912 and the external connectors 820. So far, the fabrication of a semiconductor structure 10a has been completed.

The semiconductor structure 10a may include the composite redistribution structure, the first interconnect device 300 and the IC package component 910. The composite redistribution structure includes the first redistribution structure 100, the second redistribution structure 200 and the third redistribution structure 400a. The second redistribution structure 200 is located between the first redistribution structure 100 and the third redistribution structure 400a. The first interconnect device 300 is embedded in the second redistribution structure 200. The first interconnect device 300 includes the plurality of metal connectors 330 leveled with the surface 220d of the second redistribution structure 200 and electrically connected to the third redistribution structure 400a. The IC package component 910 is disposed over the third redistribution structure 400a and electrically connected to the first interconnect device 300 via the third redistribution structure 400a. Furthermore, the semiconductor structure 10a may also include the substrate component 700, and the composite redistribution structure is interposed between and electrically coupled to the substrate component 700 and the IC package component 910. Here, the first redistribution structure 100 may be overlying the substrate component, and the third redistribution structure 400a mat be underlying the IC package component 910.

Since the first interconnect devices 300 are embedded in the second redistribution structure 200 and directly connected to the third redistribution structure 400a without using solder connections (no underfill and solder bump are required), the signal transmission path between the IC package component 910 and the first interconnect devices 300 can be reduced and the power integrity of the semiconductor structure 10a can be improved. Furthermore, since the connection between the first interconnect devices 300 and the third redistribution structure 400a does not use solder connection, the manufacturing process of the semiconductor structure 10a can be simplified and cost effective. Further, sine the signal transmission path between the IC package component 910 and the first interconnect devices 300 is reduced, the bandwidth or speed of electrical signals communicated by IC package component 910 may be increased, thereby improving high-speed operation. In addition, the placement of the first interconnect devices 300 (i.e., attached on any one of the redistribution layers 230a, 230b, 230c as shown in FIG. 1E) may allow a larger routing space between the first redistribution structure 100 and the substrate component 700 to be provided for more efficient routing, and if the first interconnect devices 300 are capacitors, the capacitor capacity of the semiconductor structure 10a (i.e., power hungry device) can be increased.

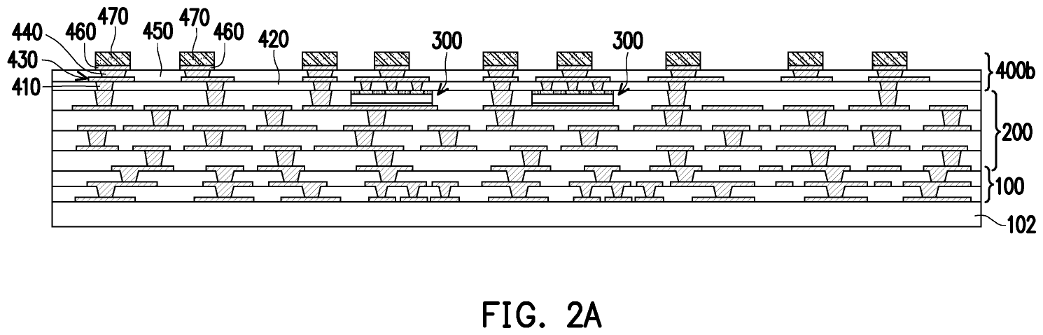

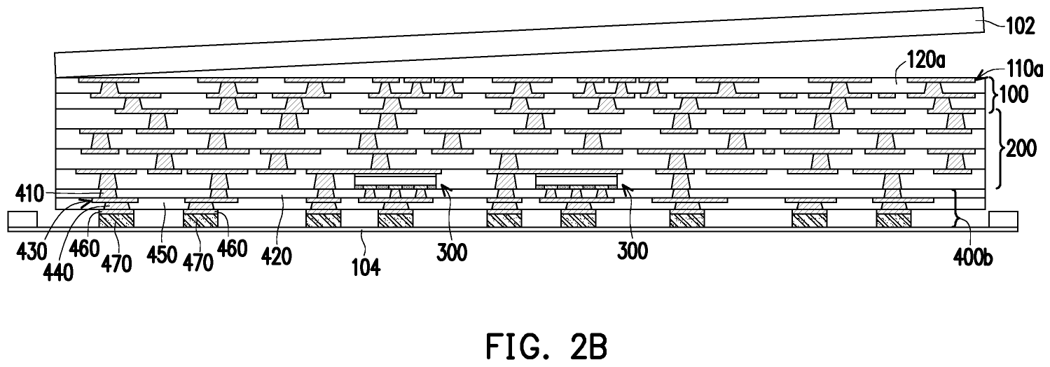

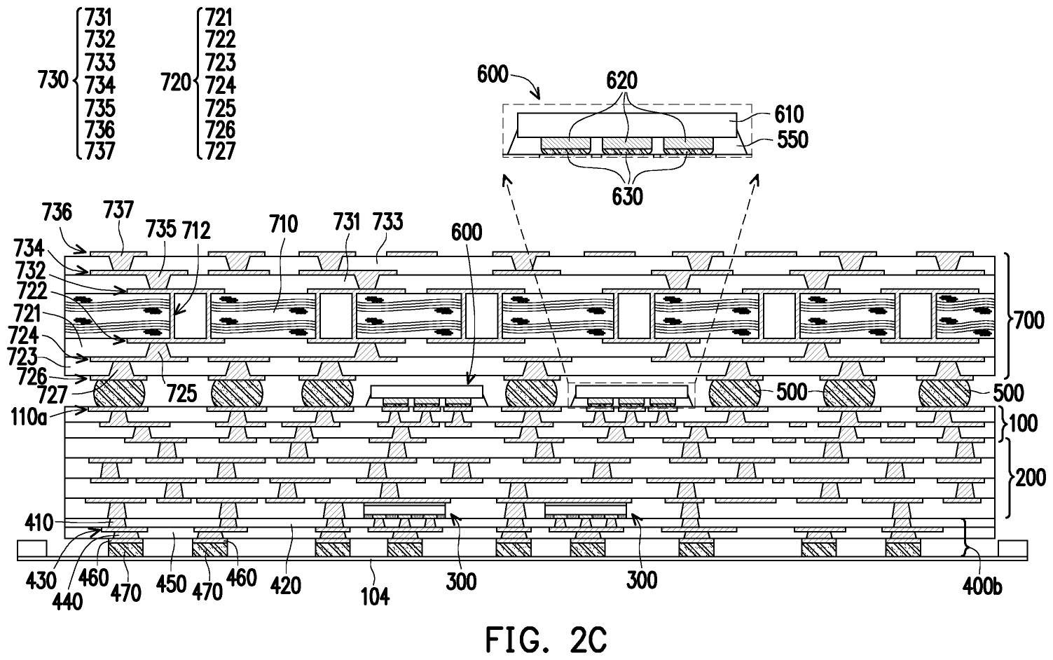

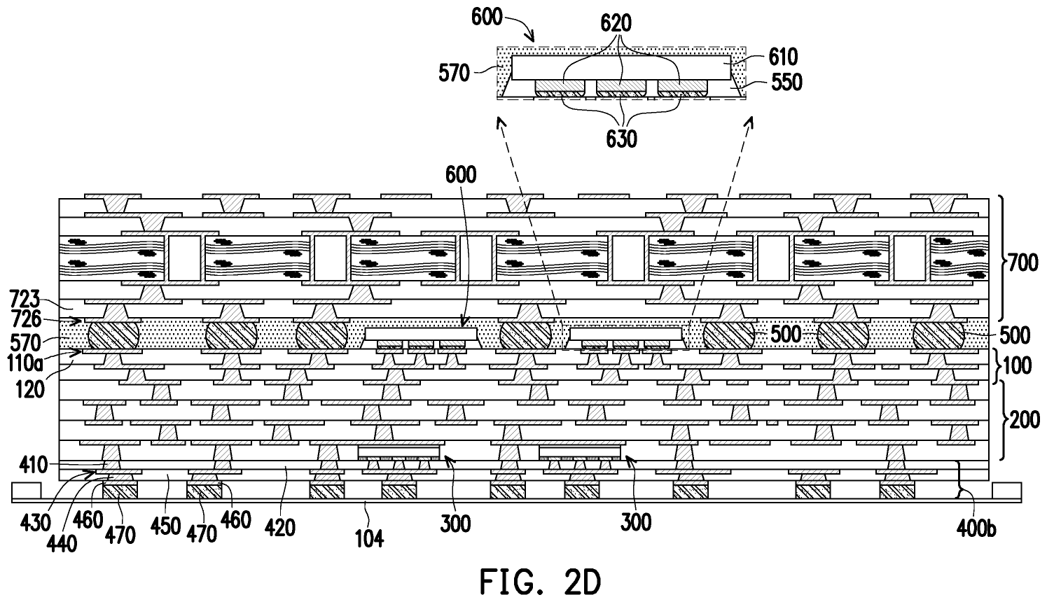

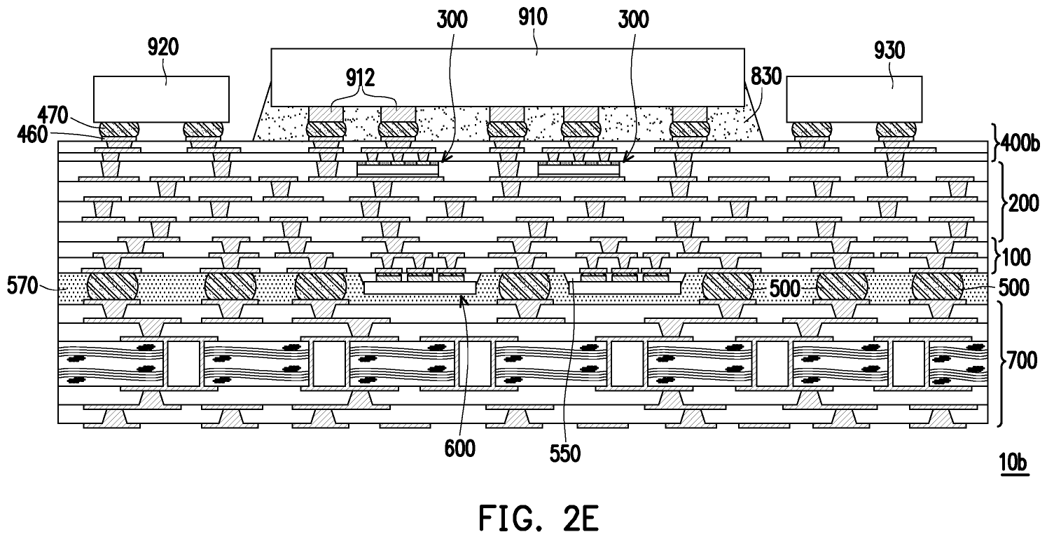

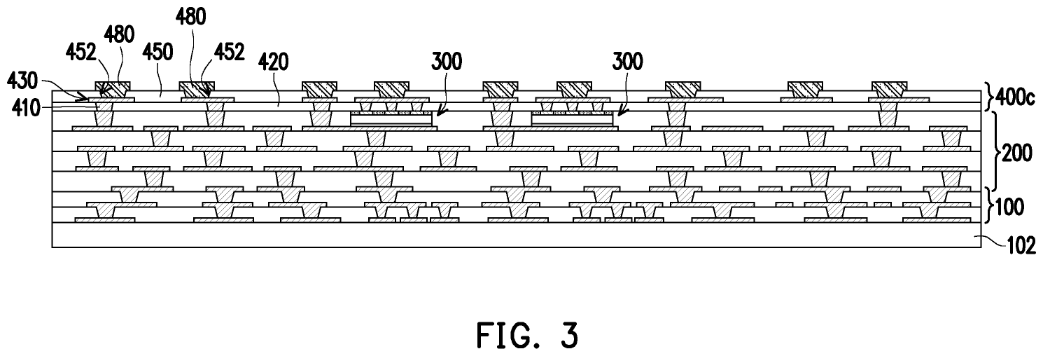

FIGS. 2A-2E are schematic cross-sectional views of partial steps of a manufacturing method of a semiconductor structure according to another embodiment of the disclosure. FIG. 3 is a schematic cross-sectional view of a third redistribution structure according to some embodiments. Referring to FIG. 2A and with reference to FIG. 1I, the third redistribution structure 400b in FIG. 2A is similar to the third redistribution structure 400a in FIG. 1I, except that in this embodiment, the third redistribution structure 400b further includes a plurality of vias 440, a dielectric layer 450, a plurality of pads 460 and a plurality of external connectors 470. For example, in this embodiment, the process starts with the step described in FIG. 1A and proceeds to the step described in FIG. 1I, and then the vias 440 may be formed on the redistribution layer 430 to physically and electrically couple the redistribution layer 430 and the pads 460. The dielectric layer 450 may be formed on the dielectric layer 420 to expose the vias 440, and the pads 460 may be formed on the dielectric layer 450. In some embodiments, the vias 440, the dielectric layer 450 and the pads 460 may be formed using similar materials and similar processes as the vias 410, the dielectric layer 420 and the redistribution layer 430 and further description of the vias 440, the dielectric layer 450 and the pads 460 is omitted for brevity. The external connectors 470 may be formed on each pad 460 by initially forming a layer of solder through evaporation, electroplating, printing, solder transfer, ball placement, or the like. In some embodiments, the external connectors 470 may be solder balls, controlled collapse chip connection (C4) bumps, micro bumps (e.g., μpbumps), electroless nickel-electroless palladium-immersion gold technique (ENEPIG) formed bumps, or the like. The external connectors 470 may include a conductive material such as solder, copper, aluminum, gold, nickel, silver, palladium, tin, the like, or a combination thereof. Once a layer of solder has been formed on the pads 460, a reflow may be performed in order to shape the material into the desired shapes. Details regarding this embodiment that are similar to those for the previously described embodiments in FIGS. 1A-1I will not be repeated herein.

Alternatively, referring to FIG. 3 and with reference to FIG. 2A, the third redistribution structure 400c in FIG. 3 is similar to the third redistribution structure 400b in FIG. 2A, except that in this embodiment, the vias 440 and the pads 460 are omitted. For example, in this embodiment, the dielectric layer 450 may include a plurality of openings 452, and the external connectors 480 may be formed in the openings 452 and extending on the dielectric layer 450. In some embodiments, the external connectors 480 may be formed using similar materials and similar processes as the external connectors 470 further description of the external connectors 480 is omitted for brevity.

Unless specified otherwise, the materials and the formation methods of the elements described in the below embodiments are essentially the same as the like elements, which are denoted by like reference numerals in the embodiments shown in FIGS. 1A-1M.

Referring to FIG. 2B and with reference to FIG. 2A, the structure shown in FIG. 2A may be transferred to be placed on the tape frame 104, and the first temporary carrier 102 may be released through a de-bonding process. In some embodiments, the structure is flipped over and placed on the tape frame 104, where the external connectors 470 may face downward and may be disposed on the tape frame 104. After the de-bonding process of the first temporary carrier 102, the conductive patterns 110a and the dielectric layers 120a of the first redistribution structure 100 may be accessibly revealed.

Referring to FIG. 2C, the second interconnect devices 600 may be attached to the first redistribution structure 100. FIG. 2C also shows a magnified view of an example second interconnect device 600. In some embodiments, the second interconnect device 600 includes the main body 610, the plurality of conductive connectors 620 and the solder material 630. The conductive connectors 620 may be used to make electrical connections to the main body 610. The second interconnect device 600 shown in FIG. 2C have conductive connectors 620 formed on a single side of each main body 610, but in some embodiments, a second interconnect device 600 may have conductive connectors 620 formed on both sides of each main body 610. In some embodiments, the solder material 630 may be formed on each conductive connector 620 prior to attachment. The second interconnect devices 600 may be placed on the first redistribution structure 100, for example, using e.g., a pick-and-place process. In some embodiments, once the solder material 630 of the second interconnect devices 600 is in physical contact with the first redistribution structure 100, a reflow process may be performed to bond the solder material 630 to the first redistribution structure 100 and thus attach the second interconnect devices 600 to the first redistribution structure 100. In some embodiments, the second interconnect devices 600 comprises passive devices, for example, capacitors, resistors, inductors, or the like. FIG. 2C shows two second interconnect devices 600 attached to the first redistribution structure 100, but in other embodiments, only one or more than two second interconnect devices 600 may be attached. In some embodiments, the underfill 550 is deposited in the gap between each main body 610 of the second interconnect devices 600 and the first redistribution structure 100. The underfill 550 can protect the conductive connectors 620 and provide structural support for the main body 610 of the second interconnect devices 600. In some embodiments, the underfill 550 may be cured after deposition.

With continued reference to FIG. 2C, the substrate component 700 is provided and may be bonded on the first redistribution structure 100. In some embodiments, the substrate component 700 is the core substrate which includes the core layer 710, the through core vias 712 extending through the core layer 710 for providing vertical electrical connections between two opposing sides of the core layer 710. In some embodiments, the substrate component 700 includes the fourth redistribution structure 720 and the fifth redistribution structure 730 electrically coupled by the through core vias 712, and fan-in/fan-out electrical signals. For example, some of the through core vias 712 are coupled between conductive features of the fourth redistribution structure 720 at one side of the core layer 710 and conductive features of the fifth redistribution structure 730 at an opposite side of the core layer 710. The fourth redistribution structure 720 and the fifth redistribution structure 730 each include the dielectric layers 721,723, 731, 733 and metallization patterns. Each respective metallization pattern has the line portions 722, 724, 726, 732, 734, 736 on and extending along the major surface of the respective dielectric layer 721, 723, 731, 733, and has the via portions 725, 727, 735, 737 extending through the respective dielectric layer 721, 723, 731, 733. More or fewer dielectric layers and metallization patterns may be formed in the fourth redistribution structure 720 and the fifth redistribution structure 730 than shown in FIG. 2C.

With continued reference to FIG. 2C, the fourth redistribution structure 720 may be attached to the conductive patterns 110a of the first redistribution structure 100 through conductive joints 500. For example, attaching the substrate component 700 includes placing conductive bumps of the substrate component 700 on the conductive patterns 110a of the first redistribution structure 100 and reflowing the conductive bumps to form the conductive joints (or solder connections) 500 that are physically and electrically coupled the substrate component 700 and the conductive patterns 110a of the first redistribution structure 100. In some embodiments, the conductive bumps are first formed on either the substrate component 700 or the conductive patterns 110a of the first redistribution structure 100, and then reflowed to complete the bond. In some embodiments, a singulation process is performed to form a coterminous sidewall, where the sidewall may include outer sidewalls of the third redistribution structure 400b, the second redistribution structure 200, the first redistribution structure 100, the protective layer 570 and substrate component 700.

Referring to FIG. 2D, the protective layer 570 may be formed in the gap between the first redistribution structure 100 and the substrate component 700 to securely bond the associated elements and provide structural support and environmental protection. FIG. 2D also shows a magnified view of an example second interconnect device 600. For example, the protective layer 570 surrounds the conductive joints 500, the underfill 550 and the second interconnect devices 600, and covers the conductive patterns 110a and the exposed surfaces of dielectric layer 120a of the first redistribution structure 100, and the line portions 726 and the exposed surfaces of the dielectric layer 723 of the fourth redistribution structure 720.

Referring to FIG. 2E and with reference to FIG. 2D, the structure is removed from the tape frame 104 through a de-taping process in order to accessibly expose the redistribution layer 430 for further processing. In some embodiments, after the de-taping process, the structure is flipped over and placed on another tape frame (not shown) for the subsequent mounting process, where the substrate component 700 may be attached to the tape frame. In some embodiments, the integrated circuit (IC) package component 910 and the electronic devices 920, 930 are mounted on the third redistribution structure 400b through the external connectors 470 after bonding the substrate component 700. The IC package component 910 and the electronic devices 920, 930 are physically and electrically connected to the external connectors 470 to make electrical connection between the IC package component 910 and the third redistribution structure 400b and between the electronic devices 920, 930 and the third redistribution structure 400b. The IC package component 910 may have bond pads 912 that are bonded to the external connectors 470. In some embodiments, IC package component 910 may be picked and placed over the third redistribution structure 400b and bonded to the external connectors 470 by flip-chip bonding process or other suitable bonding process. The electronic devices 920, 930 may be located in regions between adjacent the IC package component 910, and the electronic devices 920,930 may be electrically connected to the third redistribution structure 400b by the external connectors 470. The underfill layer 830 may be formed in the gap between the IC package component 910 and the third redistribution structure 400b to securely bond the IC package component 910 to the third redistribution structure 400b and to provide structural support and environmental protection. The underfill layer 830 may surround the bond pads 912, the external connectors 470 and the pads 460. So far, the fabrication of a semiconductor structure 10b has been completed.

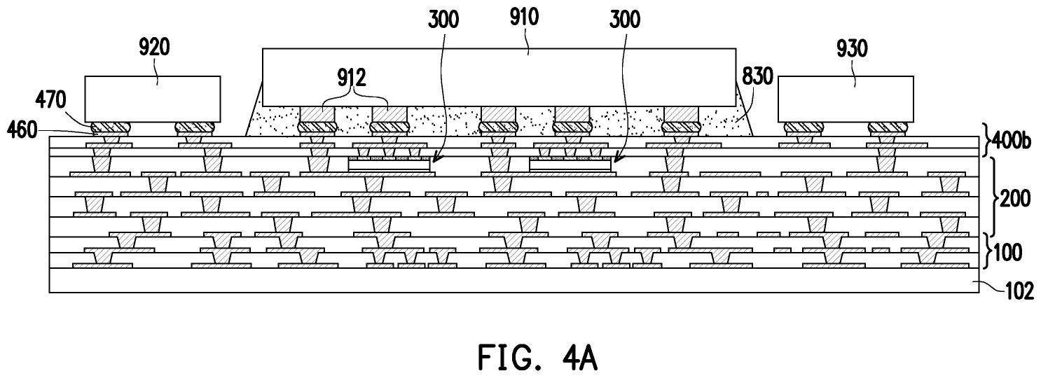

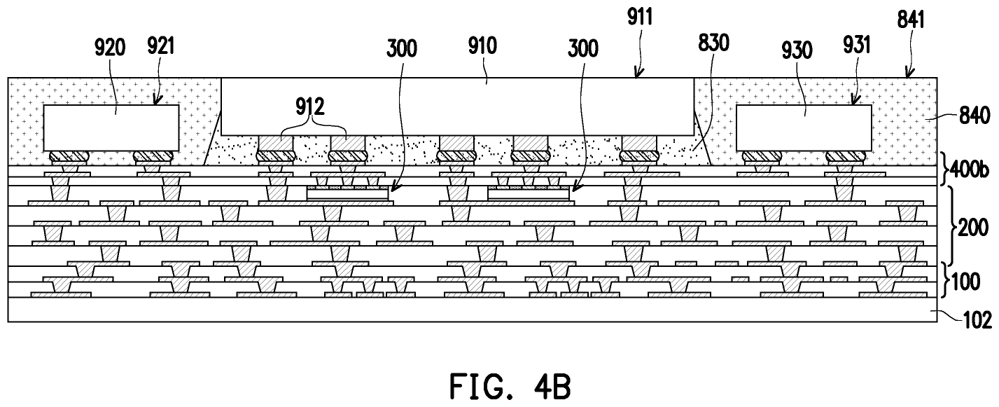

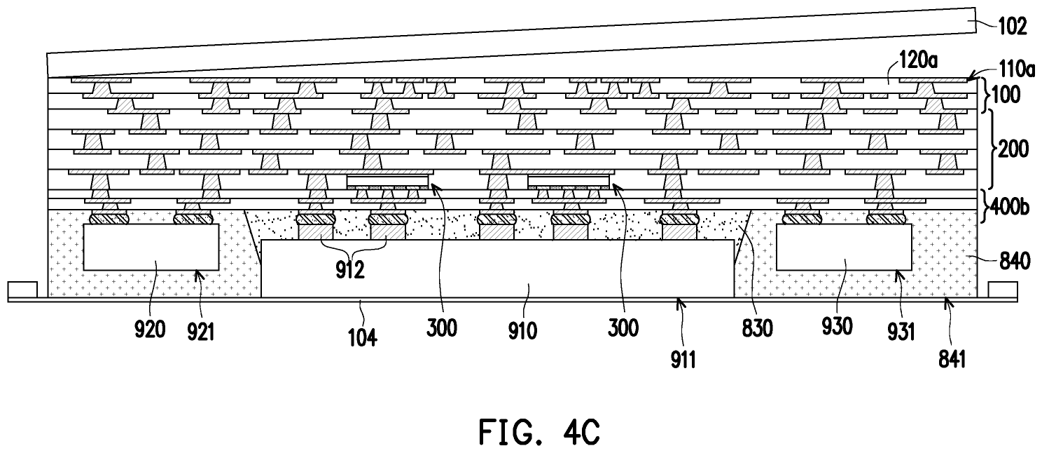

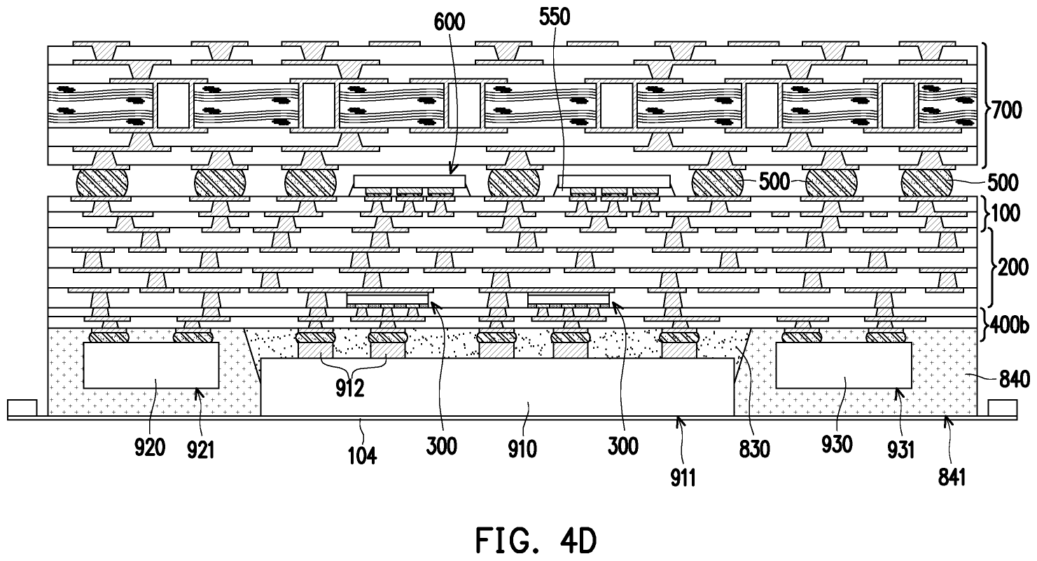

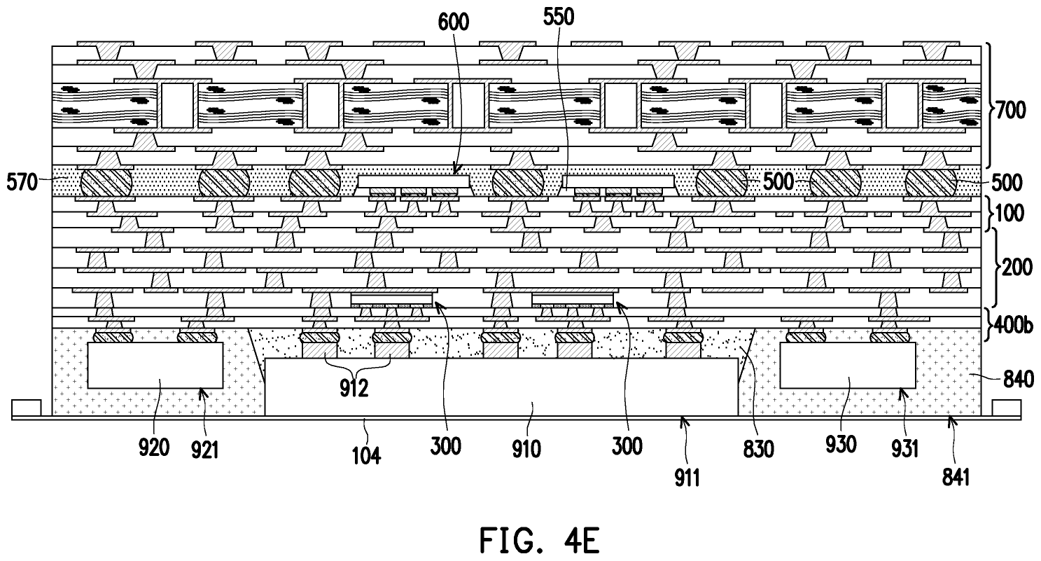

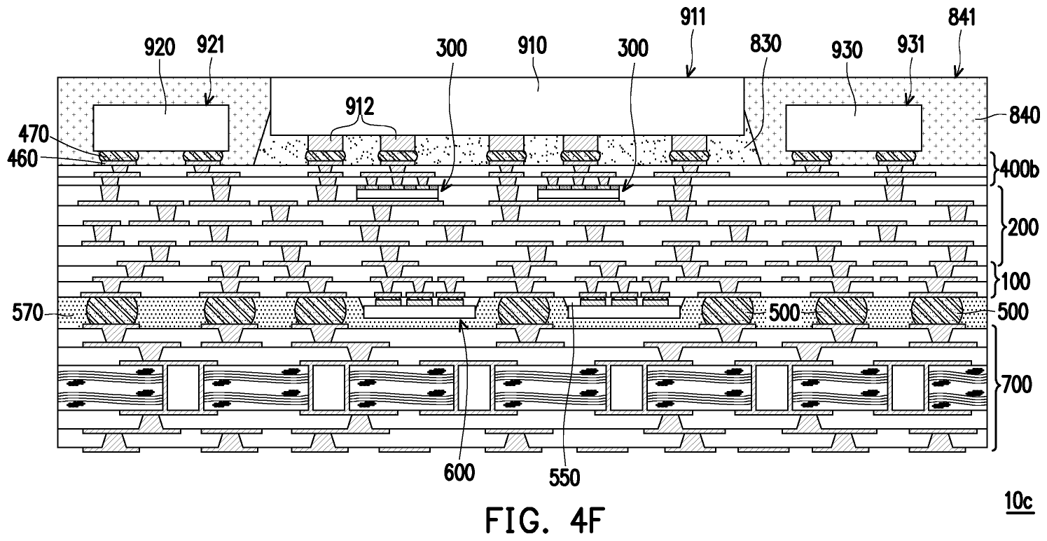

FIGS. 4A-4F are schematic cross-sectional views of partial steps of a manufacturing method of a semiconductor structure according to another embodiment of the disclosure. Unless specified otherwise, the materials and the formation methods of the elements in these embodiments are essentially the same as the like elements, which are denoted by like reference numerals in the embodiments shown in FIGS. 1A-1M.

Referring to FIG. 4A and with reference to FIG. 2A, the IC package component 910 and the electronic devices 920, 930 are mounted on the third redistribution structure 400b through the external connectors 470 before bonding the substrate component 700 (as shown in FIG. 4D). The IC package component 910 and the electronic devices 920, 930 are physically and electrically connected to the external connectors 470 to make electrical connection between the IC package component 910 and the third redistribution structure 400b and between the electronic devices 920, 930 and the third redistribution structure 400b. The IC package component 910 may have bond pads 912 that are bonded to the external connectors 470. In some embodiments, IC package component 910 may be picked and placed over the third redistribution structure 400b and bonded to the external connectors 470 by flip-chip bonding process or other suitable bonding process. The electronic devices 920, 930 may be located in regions between adjacent the IC package component 910, and the electronic devices 920,930 may be electrically connected to the third redistribution structure 400b by the external connectors 470. The underfill layer 830 may be formed in a gap between the IC package component 910 and the third redistribution structure 400b to securely bond the IC package component 910 to the third redistribution structure 400b and to provide structural support and environmental protection. The underfill layer 830 may surround the bond pads 912, the external connectors 470 and the pads 460.

Referring to FIG. 4B, the IC package component 910 and the electronic devices 920, 930 are encapsulated using an encapsulant 840. The encapsulant 840 may be, for example, a molding compound such as a resin, polyimide, PPS, PEEK, PES, epoxy molding compound (EMC), another material, the like, or a combination thereof. The encapsulant 840 may surround and/or cover the IC package component 910, the electronic devices 920, 930 and the underfill layer 830. A planarization process is performed on the encapsulant 840. The planarization process may be performed, e.g., using a mechanical grinding process, a chemical mechanical polishing (CMP) process, or the like. The planarization process removes excess portions of encapsulant 840 and exposes a top surface 911 of the IC package component 910. After the planarization process, the IC package component 910 may have a surface 911 leveled with a surface 841 of the encapsulant 841, and the encapsulant 841 bury the electronic devices 920, 930.

Unless specified otherwise, the materials and the formation methods of the elements described in the below embodiments are essentially the same as the like elements, which are denoted by like reference numerals in the embodiments shown in FIGS. 2B-2E.

Referring to FIG. 4C and with reference to FIG. 4B, the aforementioned processes may be performed in a wafer level, and the structure shown in FIG. 4B may be transferred to be placed on the tape frame 104, and the first temporary carrier 102 may be released through a de-bonding process. In some embodiments, the structure is flipped over and placed on the tape frame 104, where the top surface 911 of the IC package component 910 and the surface 841 of the encapsulant 841 may face downward and may be disposed on the tape frame 104. After the de-bonding process of the first temporary carrier 102, the conductive patterns 110a and the dielectric layers 120a of the first redistribution structure 100 may be accessibly revealed.

Referring to FIG. 4D, the same steps as FIG. 2C, the second interconnect devices 600 are attached to the first redistribution structure 100, and the underfill 550 is deposited in the gap between the second interconnect devices 600 and the first redistribution structure 100. Then, the substrate component 700 is provided and may be bonded the first redistribution structure 100 via the conductive joints (or solder connections) 500.

Referring to FIG. 4E, the same steps as FIG. 2D, the protective layer 570 may be formed in the gap between the first redistribution structure 100 and the substrate component 700 to securely bond the associated elements and provide structural support and environmental protection.

Referring to FIG. 4F and with reference to FIG. 4E, the structure is removed from the tape frame 104 through a de-taping process in order to accessibly expose the top surface 911 of the IC package component 910 and the surface 841 of the encapsulant 841. After the de-taping process, the structure is flipped over, and so far, the fabrication of a semiconductor structure 10c has been completed.

In accordance with some embodiments, a semiconductor structure includes a composite redistribution structure, a first interconnect device and an integrated circuit (IC) package component. The composite redistribution structure includes a first redistribution structure, a second redistribution structure and a third redistribution structure. The second redistribution structure is located between the first redistribution structure and the third redistribution structure. The first interconnect device is embedded in the second redistribution structure. The first interconnect device includes a plurality of metal connectors leveled with a surface of the second redistribution structure and electrically connected to the third redistribution structure. The IC package component is disposed over the third redistribution structure and electrically connected to the first interconnect device via the third redistribution structure.

In accordance with some embodiments, a semiconductor structure includes a substrate component, an integrated circuit (IC) package component, a composite redistribution structure and a first interconnect device. The IC package component is disposed over the substrate component. The composite redistribution structure is interposed between and electrically coupled to the substrate component and the IC package component. The composite redistribution structure includes a first redistribution structure, a second redistribution structure and a third redistribution structure. The first redistribution structure overlies the substrate component, the third redistribution structure underlies the IC package component, and the second redistribution structure is located between the first redistribution structure and the third redistribution structure. The first interconnect device is embedded in the second redistribution structure and electrically connected to the IC package component by the third redistribution structure.

In accordance with some embodiments, a manufacturing method of a semiconductor structure includes providing a first interconnect device having a plurality of metal connectors; forming a first redistribution structure and a second redistribution structure formed thereon, wherein the first interconnect device is attached to a redistribution layer of the second redistribution structure, and the plurality of metal connectors of the first interconnect device are leveled with a surface of the second redistribution structure; forming a third redistribution structure on the second redistribution structure, wherein the plurality of metal connectors of the first interconnect device is connected to the third redistribution structure; and provide an integrated circuit (IC) package component over the third redistribution structure, wherein the IC package component is electrically connected to the first interconnect device by the third redistribution structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a composite redistribution structure comprising a first redistribution structure, a second redistribution structure and a third redistribution structure, wherein the second redistribution structure is located between the first redistribution structure and the third redistribution structure;
a first interconnect device embedded in the second redistribution structure, wherein the first interconnect device comprises a plurality of metal connectors leveled with a surface of the second redistribution structure and electrically connected to the third redistribution structure; and
an integrated circuit (IC) package component disposed over the third redistribution structure and electrically connected to the first interconnect device via the third redistribution structure.

2. The semiconductor structure of claim 1, wherein the first interconnect device further comprises a main body and a protective layer, the plurality of metal connectors is disposed on one side of the main body, and the protective layer is disposed on the main body and fills gaps between the plurality of conductive connectors.

3. The semiconductor structure of claim 1, further comprising:
a second interconnect device disposed on a surface of the first redistribution structure relatively far away from the second redistribution structure, wherein the second interconnect device is coupled to the first redistribution structure using solder connection.

4. The semiconductor structure of claim 3, wherein the second interconnect device comprises a main body, a plurality of conductive connectors and a solder material, the plurality of conductive connectors are electrically connected to the main body, and the solder material is disposed on each of the plurality of conductive connectors.

5. The semiconductor structure of claim 4, further comprising:
an underfill disposed in a gap between the main body of the second interconnect device and the first redistribution structure.

6. The semiconductor structure of claim 1, further comprising:
a substrate component comprising a core layer, a fourth redistribution structure interposed between the core layer and the first redistribution structure, a fifth redistribution structure underlying the core layer, and through core vias penetrating through the core layer and electrically coupled to the fourth redistribution structure and fifth redistribution structure.

7. The semiconductor structure of claim 6, wherein the first redistribution structure is coupled to the substrate component using solder connection.

8. A semiconductor structure, comprising:
a substrate component;
an integrated circuit (IC) package component disposed over the substrate component;
a composite redistribution structure interposed between and electrically coupled to the substrate component and the IC package component, the composite redistribution structure comprising a first redistribution structure, a second redistribution structure and a third redistribution structure, the first redistribution structure overlying the substrate component, the third redistribution structure underlying the IC package component, and the second redistribution structure located between the first redistribution structure and the third redistribution structure; and
a first interconnect device embedded in the second redistribution structure and electrically connected to the IC package component by the third redistribution structure.

9. The semiconductor structure of claim 8, wherein the first interconnect device further comprises a main body, a plurality of metal connectors and a protective layer, the plurality of metal connectors disposed on the main body are leveled with a surface of the second redistribution structure and electrically connected to the third redistribution structure, and the protective layer is disposed on the main body and fills gaps between the plurality of conductive connectors.

10. The semiconductor structure of claim 8, further comprising:
a second interconnect device disposed on a surface of the first redistribution structure relatively far away from the second redistribution structure, wherein the second interconnect device is coupled to the first redistribution structure using solder connection.

11. The semiconductor structure of claim 10, wherein the second interconnect device comprises a main body, a plurality of conductive connectors and a solder material, the plurality of conductive connectors are electrically connected to the main body, and the solder material is disposed on each of the plurality of conductive connectors.

12. The semiconductor structure of claim 11, further comprising:
an underfill disposed in a gap between the main body of the second interconnect device and the first redistribution structure.

13. The semiconductor structure of claim 12, further comprising:
a protective layer disposed in a gap between the first redistribution structure and the substrate component to cover the second interconnect device and the underfill.

14. The semiconductor structure of claim 8, further comprising:
an encapsulant disposed on the third redistribution structure to encapsulate the IC package component, wherein a top surface of the IC package component is leveled with a surface of the encapsulant.

15. A manufacturing method of a semiconductor structure, comprising:
providing a first interconnect device having a plurality of metal connectors;
forming a first redistribution structure and a second redistribution structure formed thereon, wherein the first interconnect device is attached to a redistribution layer of the second redistribution structure, and the plurality of metal connectors of the first interconnect device are leveled with a surface of the second redistribution structure;
forming a third redistribution structure on the second redistribution structure, wherein the plurality of metal connectors of the first interconnect device is connected to the third redistribution structure; and
provide an integrated circuit (IC) package component over the third redistribution structure, wherein the IC package component is electrically connected to the first interconnect device by the third redistribution structure.

16. The manufacturing method of the semiconductor structure of claim 15, further comprising:
providing a second interconnect device on a surface of the first redistribution structure relatively far away from the second redistribution structure, wherein the second interconnect device is coupled to the first redistribution structure using solder connection.

17. The manufacturing method of the semiconductor structure of claim 16, further comprising:
providing a substrate component on the surface of the first redistribution structure relatively far away from the second first redistribution structure, wherein the substrate component is coupled to the first redistribution structure using solder connection.

18. The manufacturing method of the semiconductor structure of claim 17, further comprising:
forming a protective layer in a gap between the first redistribution structure and the substrate component to cover the second interconnect device.

19. The manufacturing method of the semiconductor structure of claim 15, further comprising:
forming an encapsulant on the third redistribution structure to encapsulate the IC package component, wherein a top surface of the IC package component is leveled with a surface of the encapsulant.

20. The manufacturing method of the semiconductor structure of claim 15, wherein the plurality of metal connectors of the first interconnect device are leveled with the surface of the second redistribution structure using a planarization process before forming the third redistribution structure.
